(19) United States
(12) Patent Application Publication
(10) Pub. No.: US 2013/0193590 A1
(43) Pub. Date: Aug. 1, 2013

(54) SEMICONDUCTOR DEVICE INCLUDING VOLTAGE CONVERTER CIRCUIT, AND METHOD OF MAKING THE SEMICONDUCTOR DEVICE

(71) Applicants: Simone Bartoli, Mandello del Lario (LC) (IT); Antonino Geraci, Monza (MB) (IT); Stefano Sivero, Capriate S. Gervasio (BG) (IT); Marco Passerini, Lozza (VA) (IT)

(72) Inventors: Simone Bartoli, Mandello del Lario (LC) (IT); Antonino Geraci, Monza (MB) (IT); Stefano Sivero, Capriate S. Gervasio (BG) (IT); Marco Passerini, Lozza (VA) (IT)

(73) Assignee: Elpida Memory, Inc., Tokyo (JP)

(21) Appl. No.: 13/363,242

(22) Filed: Jan. 31, 2012

(51) Int. Cl. H01L 23/49; H01L 21/50

(52) U.S. Cl. 257/784; 438/107; 257/E23.024; 257/E21.499

(57) ABSTRACT

A semiconductor device includes a first bonding pad, a second bonding pad, a wire bonded to a selected one of the first and second bonding pads, a power supply line electrically connected to the first bonding pad, and a voltage converter circuit coupled to the second bonding pad, the voltage converter circuit being activated when the wire is bonded to the second pad to produce an internal power voltage, which is different from a voltage received by the voltage converter circuit through the wire and the second bonding pad, and supply the internal power voltage to the power supply line, and the voltage converter circuit being deactivated when the wire is connected to the first bonding pad to allow the power supply line to receive a power voltage through the wire and the first bonding pad.

### BACKGROUND OF THE INVENTION

1. Field of the Invention

The present invention relates to a semiconductor device, and more particularly, to a semiconductor device including a voltage converter circuit.

2. Description of the Related Art

Memory device specifications cover different power supply voltage ranges according to the needs of the customer applications. Nowadays, there are two common voltage ranges, the first being a low voltage (LV) range of 1.6V-2V and the second being a high voltage (HV) range of 2.7V-3.3V. From the process and design point of view, this is a big challenge.

Each voltage range needs a specific gate oxide thickness to allow transistors not to break. The greater the oxide thickness, the higher the voltage that the transistor can sustain without breaking. However, using only high voltage transistors (e.g., transistors with a high oxide thickness) is not feasible because HV transistors have switching characteristics which are worse than low voltage transistors (e.g., transistors with a low oxide thickness) when used with low voltage supply.

One possible solution could be to develop two different processes, one for a low voltage supply range and one for a high voltage supply range. This solution has the advantage that each process can be well optimized for a particular voltage range in terms of transistor switching speed and consumption. The drawback is that developing two processes and two designs is very expensive.

Thus, instead of this possible solution, the more commonly-used solution is instead to develop only one process with both low voltage transistors and high voltage transistors, and let the design take care of the problem of the dual range voltage supply.

Usually, in the higher range of voltage supply, a down converter circuitry is used to lower the external supply to a desired internal power supply. This circuitry is designed using an HV transistor and is always connected to the external supply. This circuitry has no commutation speed requirements, so the use of HV transistors is not a limitation.

The internal digital blocks and some of the analog circuitry can be designed and fabricated with LV transistors and they use the lower internal power supply to reduce power consumption and secure sufficient reliability of each transistor. There is also particular circuitry, such as pumps and I/O buffers, that could be connected to the external power supply.

FIG. 1 illustrates a block diagram of a memory device 100, according to the related art. In particular, FIG. 1 illustrates how each block is connected to a power supply in the case of a high range (i.e. 2.7V-3.3V) external power supply.

As illustrated in FIG. 1, in the memory device 100, the down converter circuitry 135 is coupled to an external power supply pad 105, and will take care to generate an internal power supply (VPWR_INT) which is less than the external power supply (VPWR_EXT). The logic circuitry 120 that contains all the digital parts of the memory device 100 will be supplied with the internal voltage (e.g., internal power supply VPWR_INT). The analog circuitry 130 that contains all regulators, oscillators and voltage reference generators will be supplied with the internal voltage VPWR_INT.

The pumps 140 can be connected to the internal power supply (VPWR_INT) or to the external power supply (VPWR_EXT). The input/output (I/O) circuitry 150 is connected to the external output (e.g., via I/O pad 106) and is designed with HV transistors. I/O circuits are typically supplied with a dedicated power pad (e.g., Vpwr_I/O pad 107) different from VPWR_EXT and VPWR_INT. In addition, the logic circuitry 120, analog circuitry 130, the pumps 140, and the I/O circuitry 150 are coupled to a common node 185 which is coupled to the ground pad 125.

A problem that the design has to solve is how to change the internal connections to let the device work with different power supply ranges. In the case of low voltage external power supply range (i.e., 1.6V-2.2V), in fact, the internal power supply has to be connected to the external power supply and the down converter circuitry 135 has to be disabled.

A common method to accomplish a changing of the internal connections to let the device work with different power supply ranges, is to use metal options (e.g., a technique of changing a circuit function by selective layout of metal wires). In this common method, two metal masks will be generated and, according to the customer needs, one of the two metal masks will be used in the customer's memory device.

FIG. 2 illustrates another memory device 200, according to the related art.

In particular, FIG. 2 illustrates the down converter circuitry 285 of the memory device 200 in detail, and illustrates how the metal options are used to change the internal connections in the device 200.

As illustrated in FIG. 2, the down converter circuitry 285 in memory device 200 is coupled to an external power supply (VPWR_EXT) pad 201, and includes POR generator HV 205 (e.g., high voltage power-on reset generator) which generates an EN_DWN signal, down converter enable logic 210 which receives the EN_DWN signal, down converter analog core 215 which receives an output of the down converter enable logic 210 and generates signal VPWR_INT_VDC_OK, POR generator LV 220 (e.g., low voltage power-on reset generator) which receives an output of inverter 274 and generates the signal VPWR_INT_POR_OK, and VPWR_INT pull-down logic 225 which generates the signal VPWR_INT2GND which controls a gate of transistor 281.

The down converter circuitry also includes seven (7) metal options 230a-230g for changing the internal connections to let the device 200 work with different power supply voltage ranges.

Metal option 230a is open for a low voltage option and closed for a high voltage option, metal option 230b is open for a high voltage option and closed for a low voltage option, metal option 230c is open for a low voltage option and closed for a high voltage option, metal option 230d is open for a low voltage option and closed for a high voltage option, metal option 230e is open for a high voltage option and closed for a low voltage option, metal option 230f is open for a low voltage option and closed for a high voltage option, and metal option 230g is open for a high voltage option and closed for a low voltage option.

In particular, metal options 230d closed and 230e open will switch on the POR generator HV 205, while metal options 230d open and 230e closed will switch off the POR generator HV 205. The POR generator HV 205 is designed to track the external power supply and switch on the down converter enable logic 210 and the VPWR_INT pull-down logic 225 when the external power supply reaches a secure value.

The POR generator HV 205 has to work only with a high range of power supply voltages and it is designed with HV transistors. The POR generator LV 220, on the other hand, will work only with a low range of power supply voltages, so metal options 230g closed and 230f open will switch on the POR generator LV 220, while metal options 230g open and 230f closed will switch off the POR generator LV 220. POR generator LV 220 is designed with LV transistors.

Further, metal option 230a open 230b closed and 230c open are used to connect the external power supply (e.g., via VPWR_EXT Pad 201) to the internal power supply (VPWR_INT) and to cut off the down converter analog core 215 from the external power supply (VPWR_EXT) in the case of a low range of power supply voltages. On the other hand, metal option 230a closed, 230b open, and 230c closed are used in the case of a high range of power supply voltage in order to allow the down converter analog core circuit 215 to drive internal power supply line.

### SUMMARY OF THE INVENTION

A semiconductor device according to an exemplary embodiment of the disclosure includes a first bonding pad, a second bonding pad, a wire bonded to a selected one of the first and second bonding pads, a power supply line electrically connected to the first bonding pad, and a voltage converter circuit coupled to the second bonding pad, the voltage converter circuit being activated when the wire is bonded to the second pad to produce an internal power voltage, which is different from a voltage received by the voltage converter circuit through the wire and the second bonding pad, and to supply the internal power voltage to the power supply line, and the voltage converter circuit being deactivated when the wire is connected to the first bonding pad to allow the power supply line to receive a power voltage through the wire and the first bonding pad.

In another exemplary embodiment of the disclosure, a device includes a substrate including a first terminal supplied with a first power potential and a second terminal supplied with a second power potential, and a semiconductor chip mounted over the substrate. The semiconductor chip includes a first bonding pad, a second bonding pad, a third bonding pad, a power supply line electrically connected to the first bonding pad, and a voltage converter circuit coupled to the second and third bonding pads and the power supply line. The device further includes a first wire connecting the first terminal of the substrate to a selected one of the first and second bonding pads of the semiconductor chip, and a second wire connecting the second terminal of the substrate to the third bonding pad of the semiconductor chip. The voltage converter circuit of the semiconductor chip is in an activated state when the second bonding pad is the selected one to produce an internal power potential, which is different from a potential on the second bonding pad, and supply the internal power voltage to the power supply line, and the voltage converter circuit of the semiconductor chip is in a deactivated state when the first bonding pad is the selected one to allow the power supply line to receive a potential from the first bonding pad.

In still another exemplary embodiment, a method includes mounting a semiconductor chip over a package substrate, the semiconductor chip including a first bonding pad, a second bonding pad, a third bonding pad, a power supply line electrically connected to the first bonding pad, and a voltage converter circuit coupled to the second and third bonding pads and the power supply line, the package substrate including first and second external terminals; connecting a selected one of the first and second bonding pads of the semiconductor chip to the first external terminal of the package substrate, the first bonding pad being selected as the selected one when the first external terminal is to be supplied with a first power potential so that the voltage converter circuit is deactivated to allow the power supply line to receive the first power potential from the first bonding pad, the second bonding pad being selected as the selected one when the first external terminal is to be supplied with a second power potential greater than the first power potential so that the voltage converter circuit is activated to produce and supply a third power potential to the power supply line; and connecting the third bonding pad of the semiconductor chip and the second external terminal of the package substrate to each other.

### BRIEF DESCRIPTION OF THE DRAWINGS

FIG. 1 illustrates a block diagram of a memory device 100, according to the related art;

FIG. 2 illustrates another memory device 200, according to the related art;

FIG. 3 illustrates a semiconductor device 300, according to an exemplary aspect of the present invention;

FIG. 4 illustrates a semiconductor device 400, according to another exemplary aspect of the present invention;

FIG. 5 illustrates internal signals in the device 400 for the high voltage power supply bonding option according to an exemplary aspect of the present invention;

FIG. 6 illustrates internal signals in the 400 for the low voltage power supply bonding option according to an exemplary aspect of the present invention;

FIG. 7 illustrates a device 700 (e.g., a plane view) according to another exemplary aspect of the present invention;

FIG. 8A illustrates the device 700 as configured to have an activated voltage converter circuit (e.g., an activated down converter analog circuit), according to an exemplary aspect of the present invention;

FIG. 8B illustrates the device 700 as configured to have a deactivated voltage converter circuit (e.g., a deactivated down converter analog circuit), according to an exemplary aspect of the present invention;

FIG. 8C illustrates a device 800 as configured to have an activated voltage converter circuit (e.g., an activated down converter analog circuit), according to an exemplary aspect of the present invention;

FIG. 8D illustrates the device 800 as configured to have a deactivated voltage converter circuit (e.g., a deactivated down converter analog circuit), according to an exemplary aspect of the present invention;

FIG. 9 illustrates a semiconductor device 900 according to another exemplary aspect of the present invention;

FIG. 10A illustrates an exemplary circuit diagram for a voltage detector 920, according to an exemplary aspect of the present invention;

FIG. 10B illustrates another exemplary circuit diagram for the voltage detector 920, according to an exemplary aspect of the present invention;

FIG. 11A illustrates a device 1100 (including the voltage detector 920 of FIG. 10A) as configured to have an activated voltage converter circuit, according to another exemplary aspect of the present invention;

FIG. 11B illustrates the device 1100 (including the voltage detector 920 of FIG. 10A) as configured to have a deactivated voltage converter circuit, according to another exemplary aspect of the present invention;

FIG. 11C illustrates the device 1100 (including the voltage detector 920 of FIG. 10B) as configured to have an activated voltage converter circuit, according to another exemplary aspect of the present invention;

FIG. 11D illustrates the device 1100 (including the voltage detector 920 of FIG. 10B) as configured to have a deactivated voltage converter circuit, according to another exemplary aspect of the present invention;

FIG. 12 illustrates a method 1200 according to an exemplary aspect of the present invention; and

FIG. 13 illustrates a method 1300 according to another exemplary aspect of the present invention.

### DETAILED DESCRIPTION OF EXEMPLARY EMBODIMENTS OF THE INVENTION

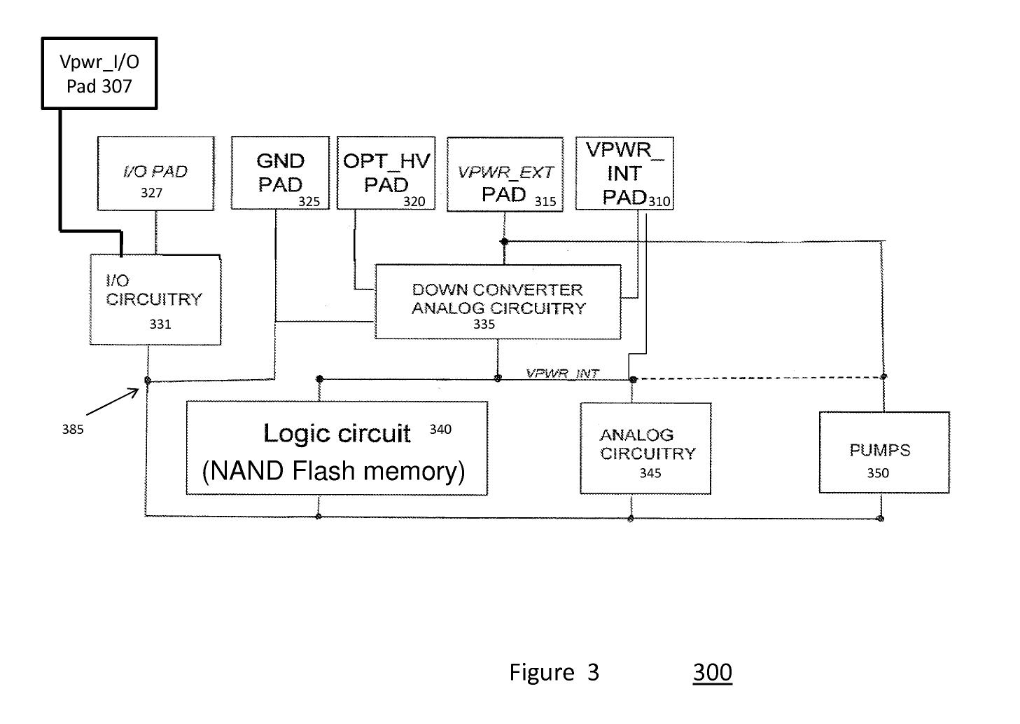

Referring now to the drawings, FIGS. 3-13 illustrate exemplary aspects of the present invention.

The exemplary aspects of the present invention may provide a method to address a problem of a dual range of voltage supply often required in semiconductor devices (e.g., memory devices). Unlike conventional methods and devices which attempt to solve the problem of dual range of voltage supply by means of metal options, configuration fuses or the like, the exemplary aspects of the present invention may solve the problem of dual range of voltage supply by using a bonding option method. That is, exemplary aspects of the present invention may provide a method which reconfigures the internal circuitry in order to work in different voltage supply ranges (e.g., two or more different voltage supply ranges) by using bonding options. An advantage of this solution is that it may allow for development of a single device and a single mask set and may allow for postponing the choice of the voltage supply range to the assembly phase.

Thus, an exemplary aspect of the present invention may provide a device (e.g., and method) which may accomplish good results using bonding options instead of the metal options (e.g., metal options 230a-230g) used in related art devices. A solution of the exemplary aspects of the present invention may be considered to be more complex than the related art devices from a design point of view, but may have great advantages over related art devices from a marketing/planning point of view. In particular, with a solution of the exemplary aspects of the present invention, it may be possible to have a unique mask set and to decide the voltage range of a semiconductor device (e.g., memory device) at an assembly phase of the semiconductor device.

FIG. 3 illustrates a semiconductor device 300, according to an exemplary aspect of the present invention. The semiconductor device 300 may include, for example, a memory device such as a NAND flash memory device.

As illustrated in FIG. 3, the semiconductor device (e.g., semiconductor chip) 300 includes a plurality of bonding pads, including VPWR_INT pad (internal power supply voltage pad) 310, VPWR_EXT pad (external power supply voltage pad) 315, OPT_HV pad 320, ground pad 325, I/O pad 327, and VPWR_I/O pad 307.

The device 300 also includes I/O circuitry 331 coupled to the I/O pad 327 and VPWR_I/O pad 307, down converter analog circuitry 335 coupled to VPWR_EXT pad 315, OPT_HV pad 320 and VPWR_INT pad 310. The device 300 also includes a logic circuit 340, analog circuitry 345, and pumps 350.

It should be noted that the I/O circuitry 331, down converter analog circuitry 335, logic circuit 340, analog circuitry 345 and pumps 350 may be formed as part of a memory circuit such as a NAND flash memory circuit. The NAND flash memory circuit may include, for example, a NAND flash memory cell array and an access control circuit to read and write data from and into the memory cell array.

As illustrated in FIG. 3, the logic circuit 340 may include a NAND flash memory including a plurality of NAND flash memory cells. The logic circuit 340 may further include a logic that contains digital parts of the memory device and/or that controls internal circuits in order to perform write, read, and erase operations on the NAND flash memory cells.

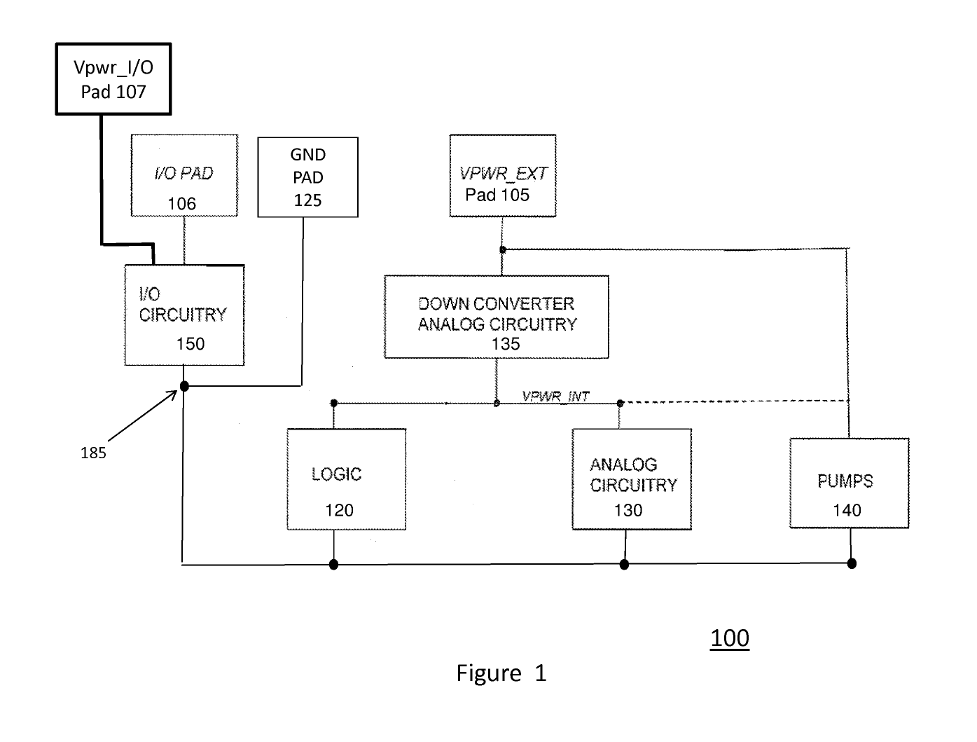

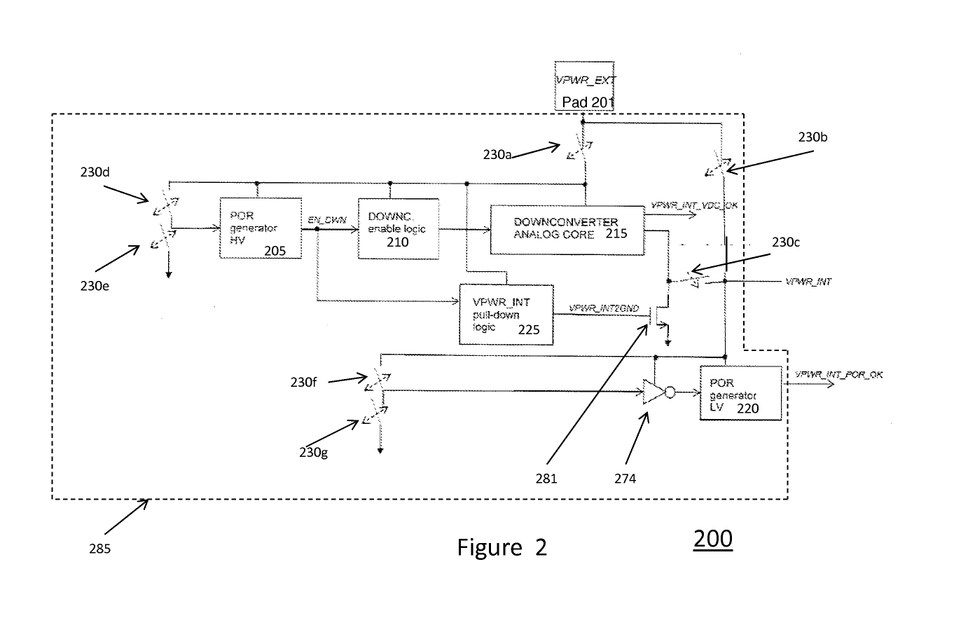

As illustrated in FIG. 3, there are several differences between the device 300 in FIG. 3 and the related art device 100 in FIG. 1. In particular, the device 300 includes the ground pad 325, OPT_HV pad 320 and VPWR_INT pad 310 which are coupled to the down converter analog circuitry 335. In addition, the logic circuit 340, analog circuitry 345, the pumps 350, I/O circuitry 331 and down converter analog circuitry 335 are coupled to a common node 385 which is coupled to the ground pad 325.

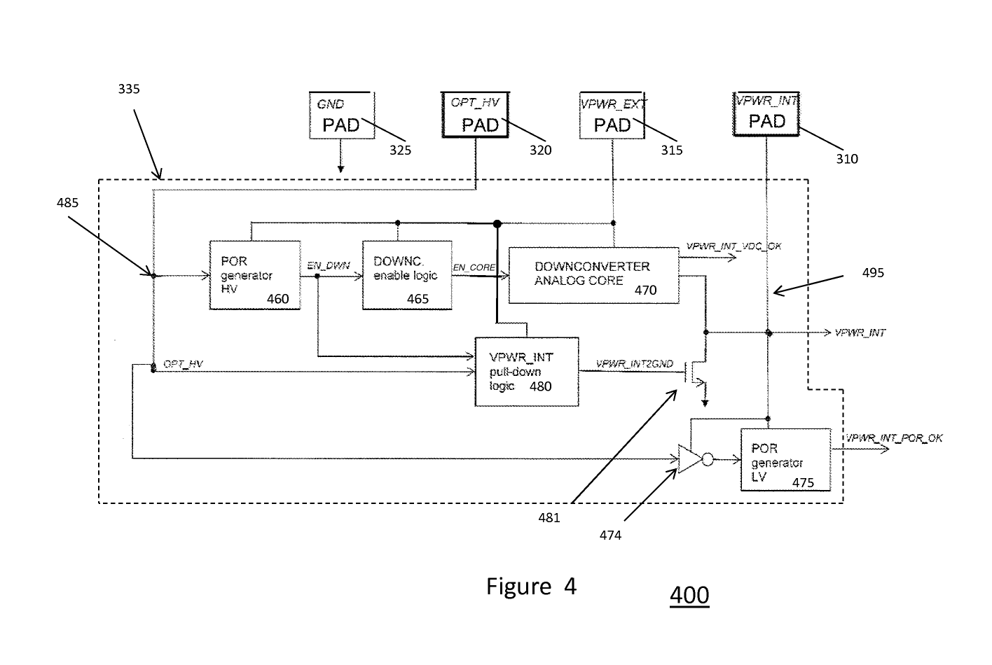

FIG. 4 illustrates a semiconductor device 400 (e.g., semiconductor chip), according to another exemplary aspect of the present invention. In particular, FIG. 4 illustrates an implementation of a solution to a problem of the related art devices (e.g., changing the internal connections to let the device work with different ranges of power supply), according to an exemplary aspect of the present invention.

As illustrated in FIG. 4, the semiconductor device 400 includes the VPWR_INT pad (internal power supply voltage pad) 310, VPWR_EXT pad (external power supply voltage pad) 315, OPT_HV pad 320 and ground pad 325. The VPWR_INT pad 310 is electrically connected to the power supply line 495.

For a low voltage option, VPW_INT pad 310 is bonded to VPWR_EXT pad 315, and both are connected to a power supply (e.g., bonded to a supply pad of a package on which the device 400 is mounted), while OPT_HV pad 320 is bonded to ground pad 325 and both are connected to ground (e.g., bonded to a ground pad of a package on which the device 400 is mounted).

For a high voltage option, VPWR_EXT pad 315 is bonded to OPT_HV pad 320 and both are connected to a power supply (e.g., bonded to a power supply pad of a package on which the device 400 is mounted).

The pads 310, 315, 320 and 325 are connected to the voltage converter circuit 335 (e.g., down converter analog circuitry) which includes POR generator HV 460 (e.g., high voltage power-on reset generator) which receives the OPT_HV signal generated by OPT_HV pad 320 and generates an EN_DWN signal, down converter enable logic 465 which receives the EN_DWN signal, down converter analog core 470 which receives the signal EN_CORE (i.e., an output of the down converter enable logic 465) and generates an internal power supply (VPWR_INT) and signal VPWR_INT_VDC_OK, POR generator LV 475 (e.g., low voltage power-on reset generator), and VPWR_INT pull-down logic 480 which generates the signal VPWR_INT2GND which controls a gate of NMOS transistor 481. The voltage converter circuit 335 also includes an inverter 474 for inverting the OPT_HV signal, so that the POR generator LV 475 receives the inverted OPT_HV signal and generates VPWR_INT_POR_OK.

It should be noted that VPWR_INT pad 310 and OPT_HV pad 320 are not included in related art device 200. The bonding pads 310, 320 may help to allow the device 400 to work with different ranges of power supply voltages.

For example, if the device 400 has to work with high power supply voltage (e.g., 2.7V-3.3V), then the VPWR_INT pad 310 is left floating (e.g., not bonded to any other pads on the device 400 or the package on which the device 400 is mounted), and the OPT_HV pad 320 is bonded to VPWR_EXT pad 315 (e.g., the pads 320 and 315 are electrically connected by a wire to a power source pad formed on a package substrate). In this way, the voltage converter circuit 335 is “on” (e.g., activated) and the internal power supply (VPWR_INT) is controlled by the voltage converter circuit 335.

On the other hand, if the device 400 has to work with a low power supply voltage (e.g., 1.6V-2V), then VPWR_INT pad 310 is bonded together with the VPWR_EXT pad 315 (e.g., the pads 310 and 315 are electrically connected by a wire to a power source pad formed on a package substrate), and the OPT_HV pad 320 is bonded to the ground pad 325 (e.g., the pads 320 and 325 are electrically connected by a wire to a ground pad formed on a package substrate). In this way the voltage converter circuit 335 is disabled (e.g., deactivated) and the internal power supply (VPWR_INT) is connected to the external power supply (VPWR_EXT).

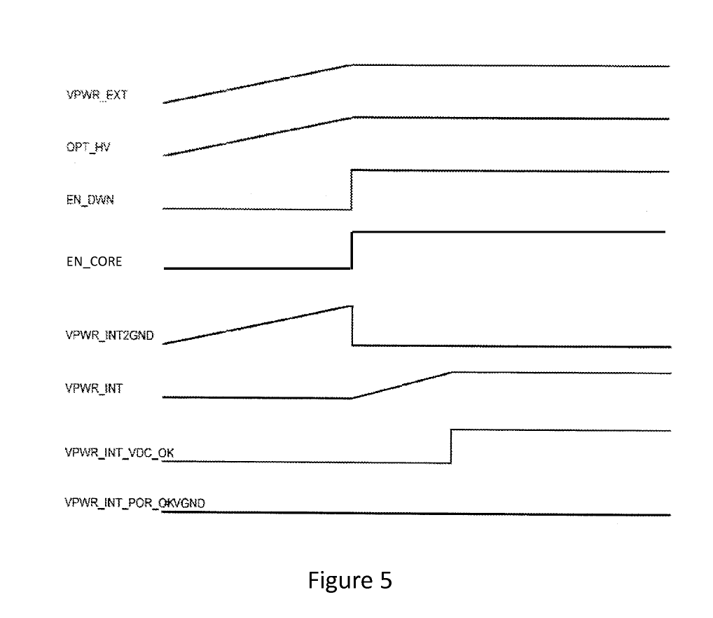

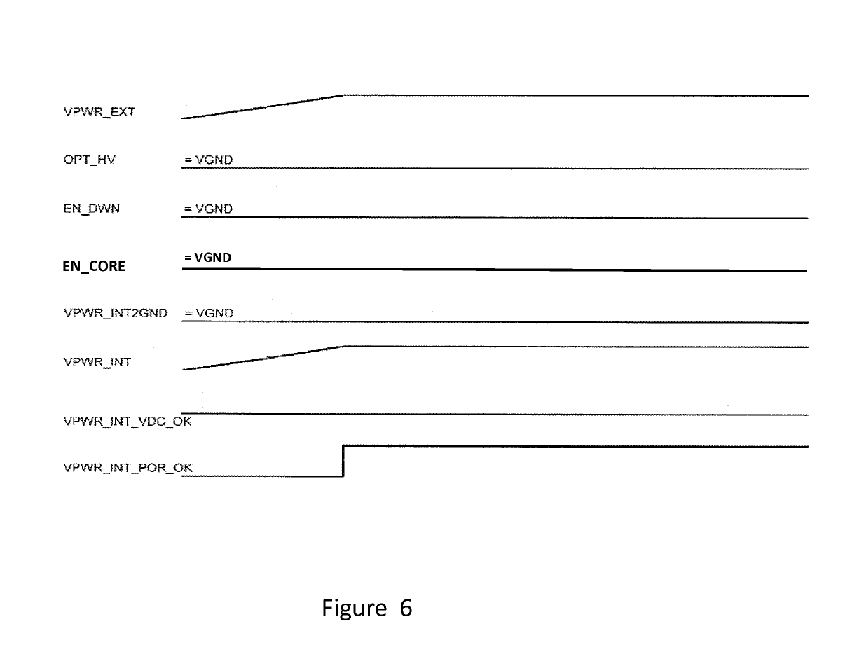

FIG. 5 illustrates internal signals in the device 400 for the high voltage power supply bonding option (e.g., OPT_HV=VPWR_EXT) during power-up, according to an exemplary aspect of the present invention, and FIG. 6 illustrates internal signals in the 400 for the low voltage power supply bonding option (e.g., OPT_HV=VGND and VPWR_EXT=VPWR_INT) during power-up, according to an exemplary aspect of the present invention. As understood by one of ordinary skill in the art, that the lines in FIGS. 5 and 6 represent an amplitude of the internal signals over time (e.g., FIGS. 5 and 6 are graphs which plot amplitude vs. time for the internal signals).

In the case where the device 400 is intended to operate in a high voltage supply range, the OPT_HV pad 320 is shorted to VPW_EXT pad 315, and VPWR_INT pad 310 is floating. Thus, as illustrated in FIG. 5, the internal signal OPT_HV goes high and most of the circuitry (e.g., POR generator HV 460, down converter enable logic 465, down converter analog core 470 and VPWR_INT pull down logic 480) is switched “on”. However, the POR generator LV 475 is switched “off”.

The POR generator HV 460 is “on” and tracks with the external power supply (VPWR_EXT), and when the external power supply reaches a safe value (e.g., VPWR_EXT, MIN which is a fixed value that allows the circuitry of the voltage converter circuit 335 to operate properly) the EN_DWN signal goes high.

This EN_DWN signal is delivered to both DOWNC enable logic 465 and the VPWR_INT pull_down logic 480. As a consequence of a rising EN_DWN signal, the DOWNC enable logic 465 enables the down converter analog core 470 by raising the signal EN_CORE. Further, as a consequence of the rising EN_DWN signal, the VPWR_INT pull down logic 480 lowers the signal VPWR_INT2GND, therefore turning “off” NMOS transistor 481. Therefore, the signal VPWR_INT is released from ground and can be driven by down converter analog core 470.

When the internal power supply VPWR_INT reaches a safe value (e.g., VPWR_INT, MIN which is a fixed value that allows the internal circuitry (supplied with VPWR_INT by the voltage converter circuit 335) to operate properly) the signal VPWR_INT_VDC_OK goes high and at this point the device 400 is ready to work.

In the case where the device 400 is intended to operate in a low voltage supply range, OPT_HV pad 320 is shorted to ground and the VPWR_INT pad 310 is shorted to the external power. As illustrated in FIG. 6, since the OPT_HV signal is ground, the POR generator HV 460 is “off”, thus keeping the EN_DWN signal grounded. Because the EN_DWN signal is kept grounded, the EN_CORE signal output from DOWNC enable logic 465 is grounded, and the VPWR_INT2GND signal output from the VPWR_INT pull down logic 480 is grounded. As a consequence, the down converter analog core 470 and the NMOS transistor 481 are kept “off”.

The internal power supply (VPWR_INT) is shorted to the external power supply (VPWR_EXT) and the external and internal power supplies rise together. The POR generator LV 475 is “on” and tracks with the internal and external power supplies. When the internal power supply reaches the safe value (as previously defined), the VPWR_INT_POR_OK signal goes high and the device 400 is ready to work.

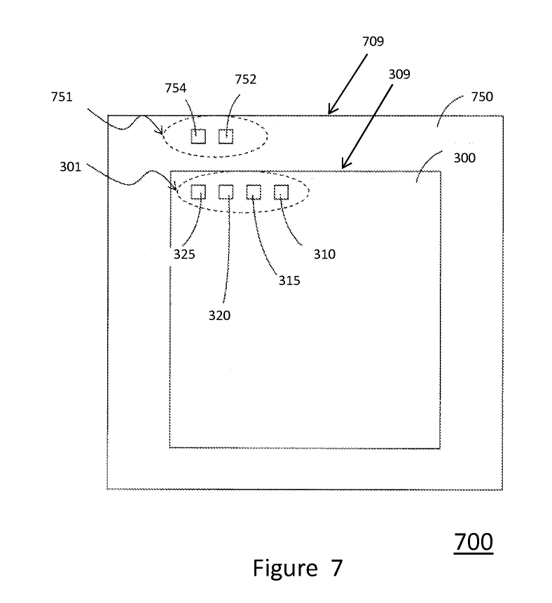

FIG. 7 illustrates a device 700 (e.g., a plane view) according to another exemplary aspect of the present invention.

As illustrated in FIG. 7, the device 700 includes a package substrate 750. A semiconductor device (e.g., semiconductor chip) such as the device 300 (e.g., device 400) is formed on (e.g., bonded to a surface of) the package substrate 750. In particular, the package substrate 750 includes a plurality of external pads 751 (e.g., external bonding pads, external terminals, etc.) such as power source pad 752 and GND pad 754, and the power source pad 752 may be supplied with one of a high power voltage and a low power voltage. It should be noted that the invention is not limited to the package substrate 750, but may instead include any substrate on which the device 300 may be formed (e.g., mounted).

As illustrated in FIG. 7, the device 300 includes a plurality of bonding pads 301 including VPWR_INT pad 310, VPWR_EXT pad 315, OPT_HV pad 320 and ground pad 325. It is needless to say, the device 300 (e.g., semiconductor chip) may include other pads than those shown in FIG. 7, and the package substrate 750 may include other external terminals than those shown in FIG. 7.

It should be noted that the ground pad 754 and power source pad 752 may be formed along an outer periphery of the package substrate 750, and the device 300 may be arranged on the package substrate 750 such that the pads 310, 315, 320 and 325 (which are formed along an outer periphery of the device 300) are proximate to the ground pad 754 and the power source pad 752. This would allow for convenient bonding by wire between the pads 310, 315, 320, 325, and the pads 752, 754.

For example, as illustrated in FIG. 7, the pads 310, 315, 320, 325 may be formed along a side 309 of the device 300, and the pads 752, 754 may be formed along a side 709 of the package substrate 750, and the device 300 may be arranged on the package substrate 750 such that the side 309 is formed adjacent to the side 709. In particular, the device 300 may be arranged on the package substrate 750 such that one or more of the pads 310, 315, 320, 325 may be electrically connected to one or more of the pads 752, 754 by a wire which extends longitudinally in a direction which is substantially perpendicular to the side 309 of the device 300.

Further, the device 300 may be arranged on the package substrate 750 such that one or more of the plurality of external terminals 751 on the package substrate 750 is aligned with one or more of the plurality of bonding pads 301 on the device 300. For example, as illustrated in FIG. 7, the external terminals 752, 754 are formed in a first line (array), and the bonding pads 310, 315, 320 and 325 are formed in a second line (array), and the ground pad 754 is aligned (e.g., in a direction perpendicular to the first and second lines) with the ground pad 325.

Further, the device 300 may be arranged on the package substrate 750 such that a distance between the plurality of external terminals on the package substrate 750 (e.g., pad 752, 754) and the plurality of bonding pads on the device 300 (e.g., pads 310, 315, 320 and 325) is optimized.

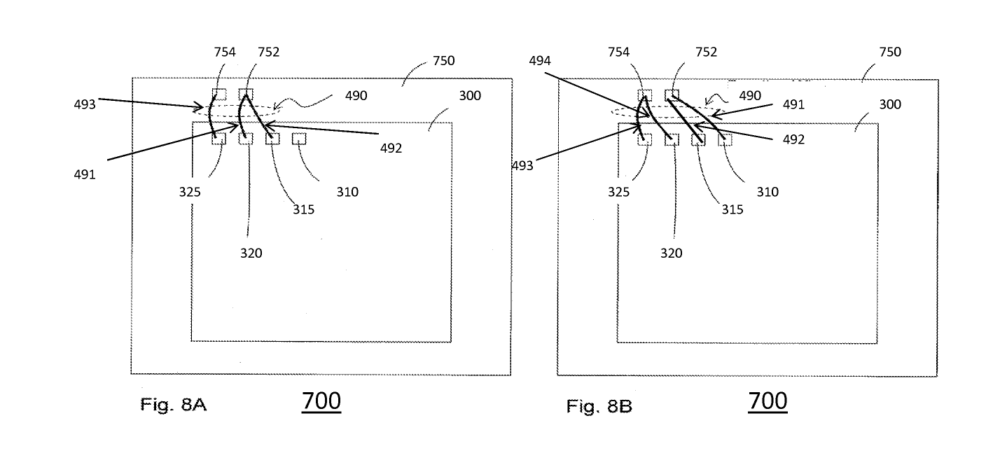

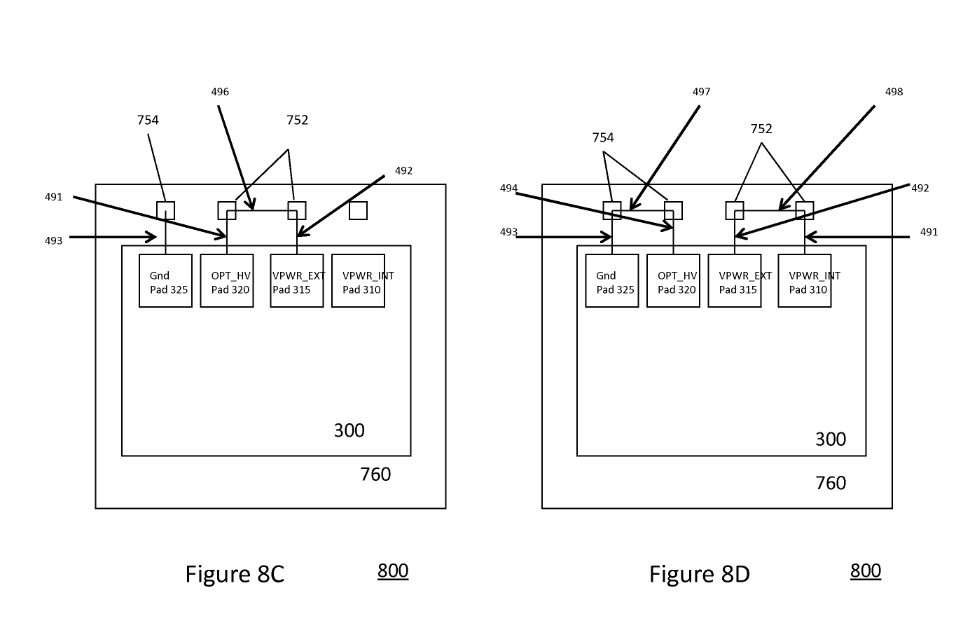

FIG. 8A illustrates the device 700 as configured to have an activated voltage converter circuit 335 (e.g., an activated down converter analog circuit), according to an exemplary aspect of the present invention. That is, FIG. 8A illustrates the device 700 having a high power supply voltage bonding option.

FIG. 8B illustrates the device 700 as configured to have a deactivated voltage converter circuit 335 (e.g., a deactivated down converter analog circuit), according to an exemplary aspect of the present invention. That is, FIG. 8B illustrates the device 700 having a low power supply voltage bonding option.

In particular, FIGS. 8A and 8B illustrate an exemplary configuration for connecting the pads 310, 315, 320 and 325 on the device 300 (e.g., semiconductor chip) of FIG. 3, to the external terminals 752, 754 of the package substrate 750 via a plurality of bonding wires 490.

It should be noted that the bonding wires and the bonding pads 310, 315, 320 and 325, and external terminals 752, 754 in the device 700 may be formed of a metal such as aluminum, copper, platinum or gold, or an alloy of any one of these metals. The bonding wires 490 may have a typical diameter of about a mil for a gold wire bonding. The bonding pads 310, 315, 320 and 325, and external terminals 752, 754 may be formed in a shape such as, for example, a square shape, rectangular shape or circular shape, and may have an area typically of about 80 μm×80 μm for each of the pads 310, 315, 320 and 325, and may have an area typically of about 120 μm×200 μm for each of the terminals 752, 754 in a ball grid array (BGA) package. Of course, the invention present invention is not limited to these exemplary shapes and dimensions.

The “bonding” of the wires to the pads 310, 315, 320 and 325, and to the external terminals 752, 754 may include ball-bonding or wedge-bonding. In particular, the “bonding” of the wires 490 may include welding the wires to the pads 310, 315, 320 and 325 or external terminals 752, 754 by heat, pressure, or ultrasonic energy or some combination of these.

In particular, the device 700 may include a wire 491 which is bonded to the OPT_HV pad 320 (FIG. 8A) or the VPWR_INT pad 310 (FIG. 8B). That is, one end of the wire 491 may be connected to a power source (e.g., bonded to a power source pad 752 formed on the package substrate 750), and the other end of the wire 491 may be selectively bonded to the VPWR_INT pad 310 or OPT_HV pad 320.

The voltage converter circuit 335 (e.g., down converter analog circuitry) is coupled to the OPT_HV pad 320, and in both configurations FIGS. 8A and 8B, the device 400 includes a wire 492 that is bonded to VPWR_EXT pad 315 (e.g. third bonding pad) to supply a power supply voltage to VPWR_EXT pad 315, and a wire 493 that is bonded to ground pad 325 (e.g., fourth bonding pad) to convey a reference potential to the ground pad 325.

As illustrated in FIG. 8A, the voltage converter circuit 335 is activated when the wire 491 is bonded to the OPT_HV pad 320, so that the voltage converter circuit 335 produces an internal power voltage (VPWR_INT), which is different from a voltage (e.g., VPWR_EXT) received by the voltage converter circuit 335 through the wire 492 and VPWR_EXT pad 752, and supplies the internal power voltage to the power supply line 495.

That is, the OPT_HV pad 320 may deliver to the voltage converter circuit 335 the OPT_HV signal which is a logical signal (i.e., not the power supply of the voltage converter circuit 335), and in response to that logical signal the voltage converter circuit 335 is activated. Thus, the voltage converter circuit 335 may draw current from VPWR_EXT pad 315 (e.g., the power supply of the voltage converter circuit 335) and supply the internal voltage line which is connected to VPWR_INT pad 310 with a lower regulated voltage.

On the other hand, as illustrated in FIG. 8B, the voltage converter circuit 335 is deactivated when the wire 494 is connected to OPT_HV pad 320. Furthermore, in this case the wire 491 is connected to VPWR_INT pad 310, allowing the power supply line 495 to receive a power voltage through the wire 491 and VPWR_INT pad 310.

The circuit node 485 of FIG. 4 is configured to take a first logic level (e.g., ground potential) when the wire 494 is bonded to the OPT_HV pad 320 (see FIG. 8B) and a second logic level (e.g., power supply potential) when the wire 491 is bonded to OPT_HV pad 320 (see FIG. 8A), and the voltage converter circuit 335 is activated in response to the circuit node 485 taking the second logic level and deactivated in response to the circuit node 485 taking the first logic level.

As illustrated in FIGS. 8A and 8B, the VPWR_INT pad 310, VPWR_EXT pad 315, OPT_HV pad 320 and ground pad 325 may be arranged such that the OPT_HV pad 320 is sandwiched between the VPWR_EXT pad 315 and ground pad 325, and VPWR_EXT pad 315 is sandwiched between the VPWR_INT pad 310 and OPT_HV pad 320.

Further, as illustrated in FIG. 8A, OPT_HV pad 320 and VPWR_EXT pad 315 are connected to each other through the wires 491 and 492 when the wire 491 is bonded to OPT_HV pad 320, and as illustrated in FIG. 8B, OPT_HV pad 320 and ground pad 325 are connected to each other through the wires 493 and 494 when the wire 491 is bonded to VPWR_INT pad 310.

FIGS. 8C and 8D illustrate device 800 according to another exemplary aspect of the present invention. FIGS. 8C and 8D correspond to FIGS. 8A and 8B, respectively.

The device 800 is similar to the device 700, but the device 800 includes the semiconductor chip 300 mounted on a package substrate 760 which is different from the package substrate 750. Namely, the package substrate 760 includes external terminals in addition to the external terminals of package substrate 750, which may allow for a bonding configuration in the device 800 which is different from the bonding configuration of device 700.

In particular, in FIG. 8C, the package substrate 760 includes plural (e.g., two) power source pads 752, so that VPWR_EXT pad 315 is bonded to one of the power source pads 752 by wire 492, and OPT_HV pad 320 is bonded to another power source pad 752 by wire 491, and the power source pads 752 are shorted together by connection 496.

In FIG. 8D, the package substrate 760 includes a plural (e.g., two) power source pads 752 and plural (e.g., two) ground pads 754, so that VPWR_INT pad 310 is bonded to one of the power source pads 752 by wire 491, VPWR_EXT pad 315 is bonded to another of the power source pads 752 by wire 492, the ground pad 325 is bonded to one of the ground pads 754 by wire 493, and OPT_HV pad 320 is bonded to another of the ground pads 754 by wire 494. Further, the ground pads 754 are shorted together by connection 497, and the power source pads 752 are shorted together by connection 498.

The connections 496, 497, 498 might be, for example, a conductive material such as a metal line fabricated directly on the substrate 760.

It should be noted that the present invention is not limited to the bonding configurations of FIGS. 8A-8D. That is, the present invention may include bonding configurations other than the bonding configurations of FIGS. 8A-8D.

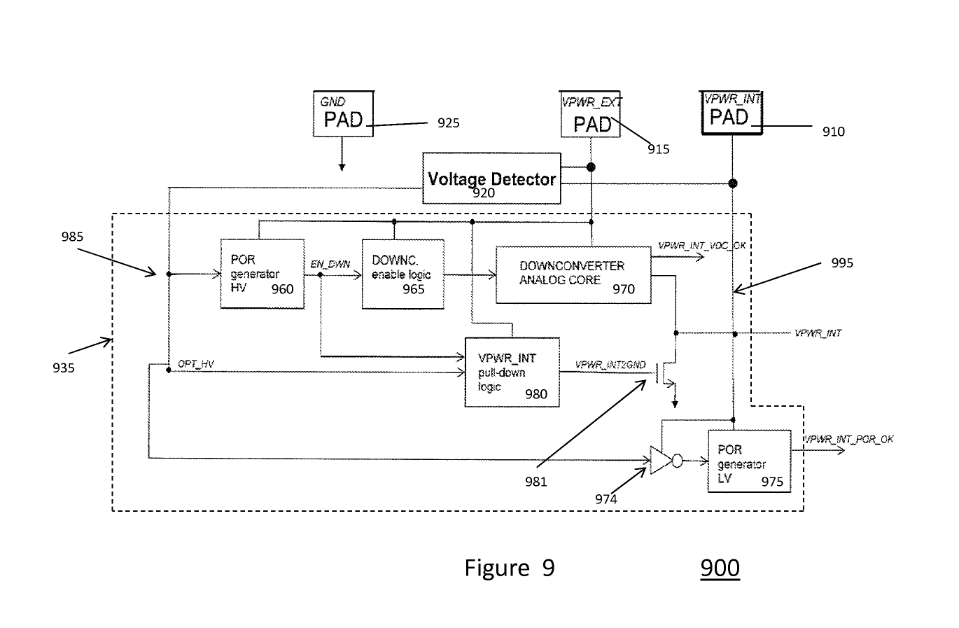

FIG. 9 illustrates a semiconductor device 900 according to another exemplary aspect of the present invention.

As illustrated in FIG. 9, the semiconductor device 900 includes the VPWR_INT pad (internal power supply voltage pad) 910, VPWR_EXT pad (external power supply voltage pad) 915, and ground pad 925.

In addition, the device 900 includes a voltage converter circuit 935 (e.g., down converter analog circuitry) which is connected to the pads 910, 915, and a voltage detector 920 which is connected to the pads 910, 915 and the voltage converter circuit 935. It should be noted that connections to GND Pad 925 are not shown for simplicity.

Similarly to the voltage converter circuit 335, the voltage converter circuit 935 includes POR generator HV 960 (e.g., high voltage power-on reset generator), down converter enable logic 965, down converter analog core 970, POR generator LV 975 (e.g., low voltage power-on reset generator), VPWR_INT pull-down logic 980, and NMOS transistor 981. The voltage converter circuit 935 also includes an inverter 974 for inverting the OPT_HV signal, so that the POR generator 975 receives the inverted OPT_HV signal.

It should be noted that similar to the device 300, in addition to the voltage converter circuit 935 (e.g., down converter analog circuitry), the device 900 may also include I/O circuitry, logic circuitry, analog circuitry and pumps which may be formed as part of a memory circuit such as a NAND flash memory circuit. The NAND flash memory circuit may include, for example, a NAND flash memory cell array and an access control circuit to read and write data from and into the memory cell array. Further, the NAND flash memory circuit may be coupled to the power supply line 995, with the NAND flash memory circuit operating on a voltage on the power supply line 995.

As illustrated in FIG. 9, the voltage detector 920 is connected to VPWR_EXT pad 915 and VPWR_INT pad 910, and may detect which of the pads 910, 915 is actually supplied with a corresponding power voltage. Thus, an output of the voltage detector 920 may serve as the “OPT_HV signal” which may be input to the voltage converter circuit 935 to activate or deactivate the voltage converter circuit 935.

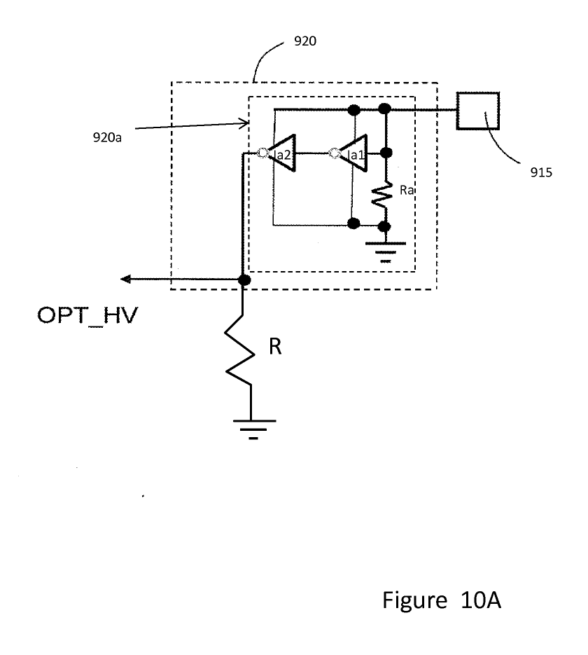

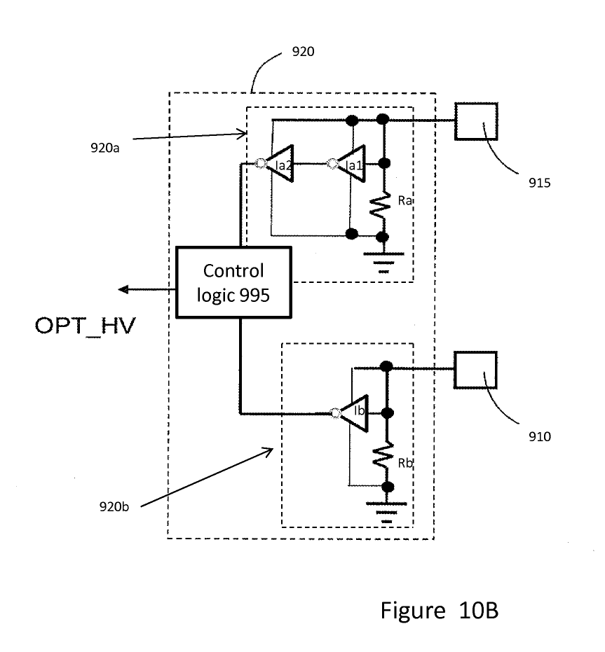

FIG. 10A and FIG. 10B illustrate exemplary circuit diagrams for the voltage detector 920, according to an exemplary aspect of the present invention.

As illustrated in FIG. 10A, in an exemplary aspect, the voltage detector 920 may include a circuit 920a coupled to the VPWR_EXT pad 915. The circuit 920a includes a resistance Rₐ which is coupled to ground, a first inverter Iₐ₁ coupled to the resistance Rₐ, and a second inverter Iₐ₂ which inverts an output of the inverter Iₐ₁. An output of the circuit 920a is coupled to a resistance 990 which is coupled to ground. The output of circuit 920 serves as an output of the voltage detector 920 which serves as the OPT_HV signal in the device 900.

As illustrated in FIG. 10B, in another exemplary aspect, the voltage detector 920 may include a first circuit 920a coupled to the VPWR_EXT pad 915, and a second circuit 920b coupled to the VPWR_INT pad 910. Similar to the exemplary aspect of FIG. 10A, the first circuit 920a includes a resistance Rₐ which is coupled to ground, a first inverter Iₐ₁ coupled to the resistance Rₐ, and a second inverter Iₐ₂ which inverts an output of the inverter Iₐ₁. The second circuit 920b includes a resistance R_{b} which is coupled to ground and an inverter I_{b} coupled to the resistance R_{b}. An output of the circuit 920b and an output of circuit 920a are coupled to control logic 995, and an output of the control logic 995 forms an output of the voltage detector 920 which serves as the OPT_HV signal in the device 900.

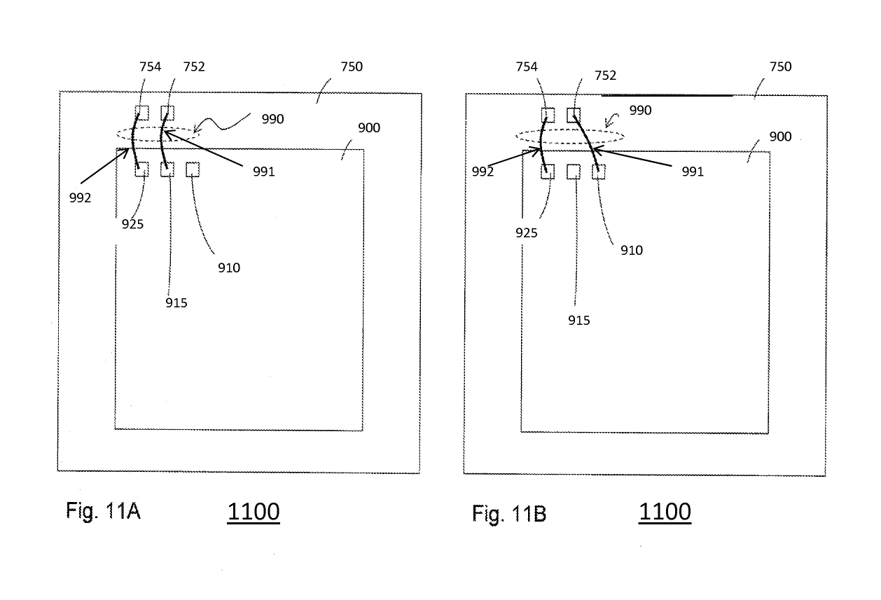

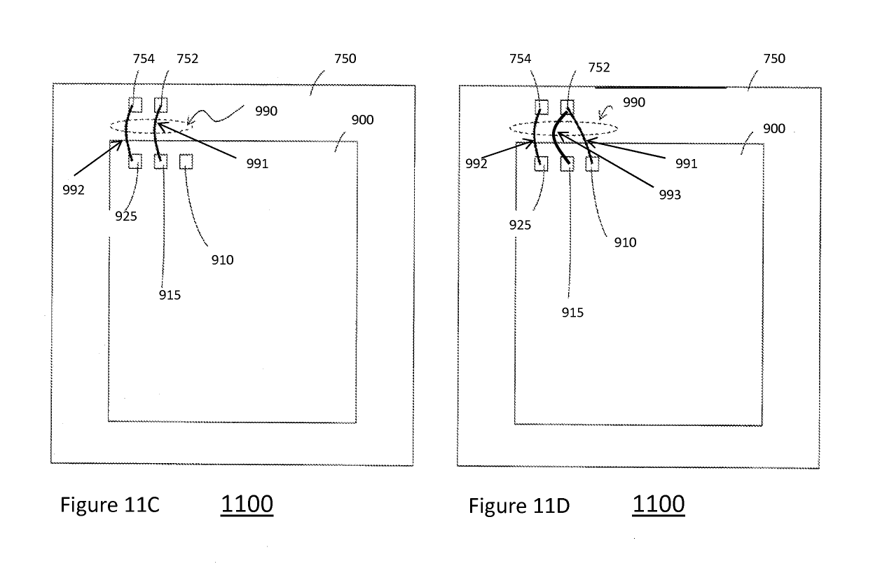

FIGS. 11A and 11B illustrate a device 1100 (including the voltage detector 920 (not illustrated) of FIG. 10A) according to another exemplary aspect of the present invention.

In particular, FIGS. 11A and 11B illustrate how the pads 910, 915 and 925 on the chip 900 in FIG. 9 may be connected via a plurality of bonding wires 990 including bonding wires 991, 992 to the terminals 752, 754 of the package substrate 750 when a voltage detector 920 such as the one depicted in FIG. 10A is employed. Similarly to FIG. 8A, FIG. 11A illustrates a case of supplying high power voltage so that the voltage converter circuit 935 is activated, whereas FIG. 11B illustrates a case of supplying low power voltage so that the voltage converter circuit 935 is deactivated.

As is apparent from FIGS. 9, 11A and 11B, when the VPWR_EXT pad 915 of the device 900 (e.g., chip 900) is connected to the power source terminal 752 of the package substrate 750 to receive the high power voltage and the VPWR_INT pad 910 is left disconnected, the voltage detector 920 produces the OPT_HV signal of “high” level, so that the voltage converter circuit 935 (e.g., down-converter) is activated. On the other hand, when the VPWR_INT pad 910 of the chip is connected to the power source terminal 752 of the package substrate 750 to receive the low power voltage and the VPWR_EXT pad 915 is left disconnected, the voltage detector 920 produces the OPT_HV signal of “low” level to deactivate the voltage converter circuit 935.

In particular, referring to FIGS. 9 and 11A and 11B, the voltage detector 920 may be coupled to VPWR_EXT pad 915 and the circuit node 985. The voltage detector 920 may control the voltage converter circuit 935 to take a first logic level by detecting the wire 991 not being bonded to VPWR_EXT pad 915 (FIG. 11A) and a second logic level by detecting the wire 991 being bonded to VPWR_EXT pad 915 (FIG. 11B).

In addition, as illustrated in both FIGS. 11A and 11B, the wire 992 may be bonded to the ground pad 925 to convey a reference potential to the ground pad 925. Further, the bonding pads 910, 915 and 925 may be arranged in line such that VPWR_EXT pad 915 is sandwiched between the VPWR_INT pad 910 and the ground pad 925.

It should be noted that the embodiment represented in FIG. 9 featuring voltage detector 920 of FIG. 10A and bonding scheme of FIGS. 11A and 11B can be used if all of the circuit blocks except the I/O circuit inside the chip 900 are connected to internal power supply line which is connected to VPWR_INT pad 910. This is evident considering the bonding scheme proposed in FIGS. 11A and 11B. In fact, if the chip 900 is configured to work with an external high voltage power supply, the pad VPWR_EXT 915 in FIG. 11A is directly connected to the external high voltage supply through bonding wire 991 and pad 752, while pad VPWR_INT 910 is left disconnected and is, therefore, driven to a lower supply voltage by the voltage converter circuit 935.

On the other hand, if the chip 900 is configured to work with a low external voltage power supply, the VPWR_EXT pad 915 is left disconnected and is, therefore, pulled to ground by the voltage detector 920 of FIG. 10A, while the VPWR_INT pad 910 is directly connected to the external low voltage through bonding wire 991 and pad 752 in FIG. 11B.

From the above description, it should be evident that no circuit except for the voltage converter circuit 935 should be connected to VPWR_EXT pad 915, the pad 915 being pulled to ground in one bonding condition (FIG. 11B).

In some applications, it would be desirable to supply some circuits inside the chip 900 directly with VPWR_EXT. For example, some circuits such as charge pumps (e.g., pumps 350 in FIG. 3) might be connected to VPWR_EXT to exploit the benefits of higher power supply when the device (e.g., device 1100) is configured to work with high external power supply and lower internal power supply.

FIGS. 11C and 11D illustrate a device 1100 (including the voltage detector 920 (not illustrated) of FIG. 10B), according to another exemplary aspect of the present invention.

As noted above, the voltage detector 920 of in FIG. 10B includes a first circuit 920a coupled to the VPWR_EXT pad 915, and a second circuit 920b coupled to the VPWR_INT pad 910, and the output of the circuit 920b and an output of circuit 920a are coupled to control logic 995, and an output of the control logic 995 forms an output of the voltage detector 920 which serves as the OPT_HV signal in the device 900.

It should also be noted that the embodiment represented in FIG. 9 featuring voltage detector 920 of FIG. 10B and bonding scheme of FIGS. 11C and 11D can be used if some of the circuit blocks inside the chip 900 are connected to VPWR_EXT pad 915. This is evident considering the bonding scheme proposed in FIGS. 11C and 11D. In fact, the VPWR_EXT pad 915 is connected to pad 752 in the configuration of FIG. 11C and the configuration of FIG. 11D. This is accomplished by using bonding wire 991 in FIG. 11C and bonding wire 993 in FIG. 11D.

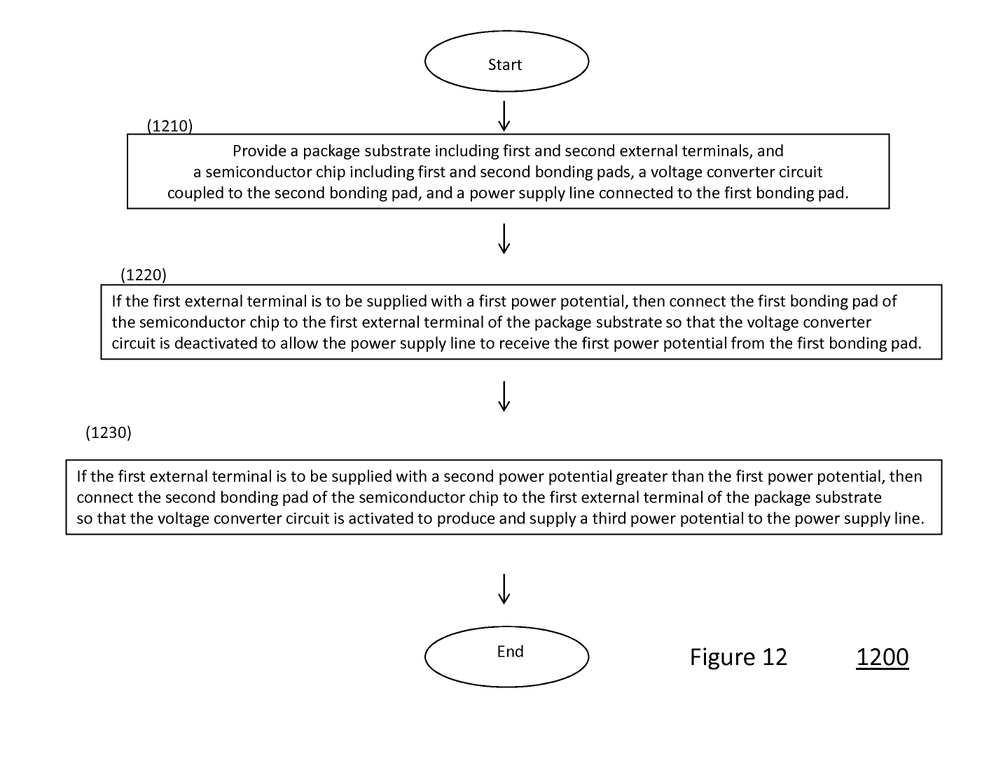

FIG. 12 illustrates a method 1200 according to an exemplary aspect of the present invention.

As illustrated in FIG. 12, the method 1200 includes providing (1210) a package substrate including first and second external terminals, and a semiconductor chip including first and second bonding pads, a voltage converter circuit coupled to the second bonding pad, and a power supply line connected to the first bonding pad, if the first external terminal is to be supplied with a first power potential, then connecting (1220) the first bonding pad of the semiconductor chip to the first external terminal of the package substrate so that the voltage converter circuit is deactivated to allow the power supply line to receive the first power potential from the first bonding pad, and if the first external terminal is to be supplied with a second power potential greater than the first power potential, then connecting (1230) the second bonding pad of the semiconductor chip to the first external terminal of the package substrate so that the voltage converter circuit is activated to produce and supply a third power potential to the power supply line.

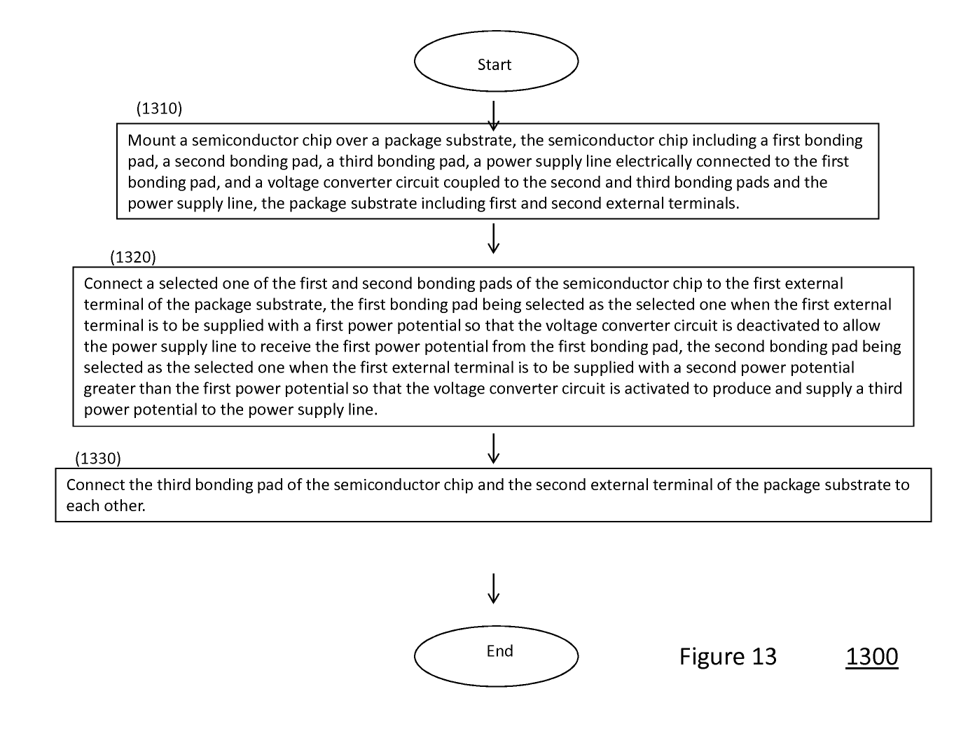

FIG. 13 illustrates a method 1300 according to another exemplary aspect of the present invention.

As illustrated in FIG. 13, the method 1300 includes mounting (1310) a semiconductor chip over a package substrate, the semiconductor chip including a first bonding pad, a second bonding pad, a third bonding pad, a power supply line electrically connected to the first bonding pad, and a voltage converter circuit coupled to the second and third bonding pads and the power supply line, the package substrate including first and second external terminals.

The method 1300 also includes connecting (1320) a selected one of the first and second bonding pads of the semiconductor chip to the first external terminal of the package substrate, the first bonding pad being selected as the selected one when the first external terminal is to be supplied with a first power potential so that the voltage converter circuit is deactivated to allow the power supply line to receive the first power potential from the first bonding pad, the second bonding pad being selected as the selected one when the first external terminal is to be supplied with a second power potential greater than the first power potential so that the voltage converter circuit is activated to produce and supply a third power potential to the power supply line.

The method 1300 also includes connecting (1330) the third bonding pad of the semiconductor chip and the second external terminal of the package substrate to each other.

Although it is not illustrated in FIG. 13, the method 1300 may also include connecting a fourth bonding pad of the semiconductor chip, which is connected to the voltage converter circuit, to the first external terminal of the package substrate, the second external terminal being connected to the second bonding pad when the first external terminal is to be supplied with the first power potential to deactivate the voltage converter, and the first external terminal being connected to the second bonding pad when the first external terminal is to be supplied with the second power potential to activate the voltage converter circuit. The method 1300 may also include making a NAND flash memory circuit of the semiconductor chip operate on a voltage on the power supply line.

With its unique and novel features, the exemplary aspects of the present invention may provide a method and device which may reconfigure internal circuitry in order to work in two different voltage supply ranges by means of bonding options.

While the invention has been described in terms of one or more embodiments, those skilled in the art will recognize that the invention can be practiced with modification within the spirit and scope of the appended claims. Specifically, one of ordinary skill in the art will understand that the drawings herein are meant to be illustrative, and the design of the inventive assembly is not limited to that disclosed herein but may be modified within the spirit and scope of the present invention.

Further, Applicant's intent is to encompass the equivalents of all claim elements, and no amendment to any claim of the present application should be construed as a disclaimer of any interest in or right to an equivalent of any element or feature of the amended claim.

What is claimed is:

1. A semiconductor device comprising:
a first bonding pad;
a second bonding pad;
a wire bonded to a selected one of the first and second bonding pads;
a power supply line electrically connected to the first bonding pad; and
a voltage converter circuit coupled to the second bonding pad, the voltage converter circuit being activated when the wire is bonded to the second bonding pad to produce an internal power voltage, which is different from a voltage received by the voltage converter circuit through the wire and the second bonding pad, and supply the internal power voltage to the power supply line, and the voltage converter circuit being deactivated when the wire is connected to the first bonding pad to allow the power supply line to receive a power voltage through the wire and the first bonding pad.

2. The device as claimed in claim 1, wherein the device further comprises a circuit node configured to take a first logic level when the wire is bonded to the first bonding pad and a second logic level when the wire is bonded to the second bonding pad, and the voltage converter is activated in response to the circuit node taking the second logic level and deactivated in response to the circuit node taking the first logic level.

3. The device as claimed in claim 2, wherein the wire is a first wire and the second bonding pad is electrically connected to the circuit node, and the device further comprises a third bonding pad and a second wire that is bonded to the third bonding pad and a third wire that is bonded to the second bonding pad when the first wire is bonded to the first bonding pad, the third wire supplying the second bonding pad with a first potential when the first wire is bonded to the first bonding pad and the first wire supplying the second bonding pad with a second potential when the first wire is bonded to the second bonding pad.

4. The device as claimed in claim 3, wherein the second potential is substantially equal in level to the voltage received by the voltage converter circuit through the second wire and the third bonding pad.

5. The device as claimed in claim 4, wherein the first potential is a ground potential.

6. The device as claimed in claim 2, wherein the wire is a first wire and the device further comprises a third bonding pad and a second wire that is bonded to the third bonding pad, and a fourth bonding pad and a third wire bonded to the fourth bonding pad to convey a reference potential thereto, and the first, second, third and fourth bonding pads are arranged such that the second bonding pad is sandwiched between the third and fourth bonding pads and the third bonding pad is sandwiched between the first and second bonding pads.

7. The device as claimed in claim 6, wherein the second and third bonding pads are connected to each other through the first and second wires when the first wire is bonded to the second bonding pad and the second and fourth bonding pads are connected to each other through the third wire and a fourth wire bonded to the second bonding pad when the first wire is bonded to the first bonding pad.

8. The device as claimed in claim 2, wherein the device further comprises a voltage detector that is coupled to the first and second bonding pads and the circuit node, the voltage detector controlling the circuit node to take the first logic level by detecting the wire being bonded to the first bonding pad and the second logic level by detecting the wire being bonded to the second bonding pad.

9. The device as claimed in claim 8, wherein the device further comprises a third bonding pad and an additional wire bonded to the third bonding pad to convey a reference potential thereto, and the first, second and third bonding pads are arranged in line such that the second bonding pad is sandwiched between the first and third bonding pads.

10. The device as claimed in claim 9, wherein the device further comprises a NAND flash memory circuit coupled to the power supply line to operate on a voltage on the power supply line.

11. A device comprising:
a substrate including a first terminal supplied with a first power potential and a second terminal supplied with a second power potential;
a semiconductor chip mounted over the substrate, the semiconductor chip comprising;
a first bonding pad;
a second bonding pad;
a third bonding pad;
a power supply line electrically connected to the first bonding pad; and
a voltage converter circuit coupled to the second and third bonding pads and the power supply line;
a first wire connecting the first terminal of the substrate to a selected one of the first and second bonding pads of the semiconductor chip; and
a second wire connecting the second terminal of the substrate to the third bonding pad of the semiconductor chip;
the voltage converter circuit of the semiconductor chip being in an activated state when the second bonding pad is the selected one to produce an internal power potential, which is different from a potential on the second bonding pad, and supply the internal power voltage to the power supply line, and the voltage converter circuit of the semiconductor chip being in a deactivated state when the first bonding pad is the selected one to allow the power supply line to receive a potential from the first bonding pad.

12. The device as claimed in claim 11, wherein the semiconductor chip further comprises a fourth bonding pad, and the device further comprises a third wire connecting the first terminal of the substrate to the fourth bonding pad of the semiconductor chip, the fourth bonding pad being coupled to the voltage converter circuit to bring the voltage converter circuit into one of the activated and deactivated states.

13. The device as claimed in claim 12, wherein the second and fourth bonding pads of the semiconductor chip are connected to the first terminal of the substrate via the first and third wires, respectively, to bring the voltage converter circuit into the activated state.

14. The device as claimed in claim 12, wherein the first and fourth bonding pads of the semiconductor chip are connected to the first terminal of the substrate via the first and third wires, respectively, to bring the voltage converter circuit into the deactivated state.

15. The device as claimed in claim 12, wherein the first, second, third and fourth bonding pads of the semiconductor chip are arranged such that the second bonding pad is sandwiched between the third and fourth bonding pads and the fourth bonding pad is sandwiched between the first and second bonding pads, and the first and second terminals of the substrate are on a side corresponding to the first bonding pad and on a side corresponding to the third bonding pad, respectively.

16. The device as claimed in claim 11, wherein the semiconductor chip further comprises a voltage detector coupled to the first and second bonding pads to detect whether the selected one is the first bonding pad or the second bonding pad in response to a potential at each of the first and second bonding pads, the voltage detector being coupled to the voltage converter circuit to bring the voltage converter circuit into one of the activated and deactivated states.

17. The device as claimed in claim 11, wherein the semiconductor chip further comprises a NAND flash memory circuit coupled to the power supply line, the NAND flash memory circuit operating on a voltage on the power supply line.

18. A method comprising:
mounting a semiconductor chip over a package substrate, the semiconductor chip comprising a first bonding pad, a second bonding pad, a third bonding pad, a power supply line electrically connected to the first bonding pad, and a voltage converter circuit coupled to the second and third bonding pads and the power supply line, the package substrate comprising first and second external terminals;
connecting a selected one of the first and second bonding pads of the semiconductor chip to the first external terminal of the package substrate, the first bonding pad being selected as the selected one when the first external terminal is to be supplied with a first power potential so that the voltage converter circuit is deactivated to allow the power supply line to receive the first power potential from the first bonding pad, the second bonding pad being selected as the selected one when the first external terminal is to be supplied with a second power potential greater than the first power potential so that the voltage converter circuit is activated to produce and supply a third power potential to the power supply line; and
connecting the third bonding pad of the semiconductor chip and the second external terminal of the package substrate to each other.

19. The method as claimed in claim 18, further comprising:
connecting a fourth bonding pad of the semiconductor chip, which is connected to the voltage converter circuit, to the first external terminal of the package substrate, the second external terminal being connected to the second bonding pad when the first external terminal is to be supplied with the first power potential to deactivate the voltage converter, and the first external terminal being connected to the second bonding pad when the first external terminal is to be supplied with the second power potential to activate the voltage converter circuit.

20. The method as claimed in claim 18, further comprising:
making a NAND flash memory circuit of the semiconductor chip operate on a voltage on the power supply line.
